(19) United States
(12) Patent Application Publication
(10) Pub. No.: US 2021/0151428 A1
(43) Pub. Date: May 20, 2021

(54) INTEGRATION OF HETEROGENEOUS TRANSISTORS ON DIAMOND SUBSTRATE BY LAYER TRANSFER

(71) Applicant: QUALCOMM Incorporated, San Diego, CA (US)

(72) Inventors: Ranadeep DUTTA, Del Mar, CA (US); Je-Hsiung LAN, San Diego, CA (US); Jonghae KIM, San Diego, CA (US)

(21) Appl. No.: 16/686,377

(22) Filed: Nov. 18, 2019

(51) Int. Cl. H01L 27/06; H01L 29/66; H01L 29/778; H01L 29/20; H01L 29/16; H01L 23/66; H01L 21/02

(52) U.S. Cl. CPC H01L 27/0629; H01L 29/66462; H01L 29/7786; H01L 29/2003; H01L 2223/6672; H01L 23/66; H01L 21/02376; H01L 21/02167; H01L 29/1608

(57) ABSTRACT

A semiconductor device having heterogeneous transistors integrated on a diamond substrate with a carbonized layer. An example semiconductor device generally includes a first semiconductor die and a second semiconductor die. The first semiconductor die includes a diamond substrate, a carbonized layer disposed above the diamond substrate, and a first transistor disposed above the carbonized layer, the first transistor comprising gallium nitride. The second semiconductor die is disposed above the first semiconductor die, where the second semiconductor die includes a second transistor comprising a different semiconductor material than the first transistor.

### BACKGROUND

### Field of the Disclosure

Certain aspects of the present disclosure generally relate to electronic circuits and, more particularly, to a semiconductor device having heterogeneous transistors integrated on a diamond substrate.

### Description of Related Art

A continued emphasis in semiconductor technology is to create improved performance semiconductor devices at competitive prices. This emphasis over the years has resulted in extreme miniaturization of semiconductor devices, made possible by continued advances in semiconductor processes and materials in combination with new and sophisticated device designs. Many of the semiconductor devices that are contemporaneously being created are aimed at processing digital data. There are, however, also numerous semiconductor designs that are aimed at incorporating analog functions into devices that simultaneously process digital and analog signals, or devices that can be used for the processing of only analog signals.

An example of a semiconductor device that may incorporate analog and digital functions is a radio frequency front-end. A wireless communication device, such as a base station or user equipment, may include a radio frequency front-end for transmitting and/or receiving radio frequency signals. The radio frequency front-end may include transistors to implement various analog and digital devices, such as control circuitry, switches, duplexers, diplexers, multiplexers, power amplifiers, low noise amplifiers, mixers, etc. The devices implemented with transistors may be fabricated on a semiconductor wafer. Some of the transistor devices (such as a power amplifier) may be fabricated as discrete components and interconnected to the other devices of the radio frequency front-end.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description,” one will understand how the features of this disclosure provide advantages that include an improved radio frequency front-end for a wireless communication device.

Certain aspects of the present disclosure provide a semiconductor device. The semiconductor device generally includes a first semiconductor die and a second semiconductor die. The first semiconductor die includes a diamond substrate, a carbonized layer disposed above the diamond substrate, and a first transistor disposed above the carbonized layer, the first transistor comprising gallium nitride. The second semiconductor die is disposed above the first semiconductor die, where the second semiconductor die includes a second transistor comprising a different semiconductor material than the first transistor.

Certain aspects of the present disclosure provide a method of fabricating a semiconductor device. The method generally includes forming a first semiconductor die, wherein forming the first semiconductor die comprises forming a carbonized layer above a diamond substrate and forming a first transistor, comprising gallium nitride, above the carbonized layer. The method also includes bonding a second semiconductor die to the first semiconductor die, wherein the second semiconductor die comprises a second transistor comprising a different semiconductor material than the first transistor.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is a block diagram showing an example radio frequency front-end, in accordance with certain aspects of the present disclosure.

FIG. 2 is a cross-sectional view of an example semiconductor device having heterogeneous transistors embedded in separate semiconductor dies, where one of the semiconductor dies has a gallium nitride (GaN) transistor disposed on a carbonized layer, in accordance with certain aspects of the present disclosure.

FIG. 3A is a cross-sectional view of an example semiconductor-diamond substrate, in accordance with certain aspects of the present disclosure.

FIG. 3B is a cross-sectional view of a carbonized silicon layer of the semiconductor-diamond substrate, in accordance with certain aspects of the present disclosure.

FIG. 3C is a cross-sectional view of a cavity formed in a dielectric layer disposed above the carbonized layer, in accordance with certain aspects of the present disclosure.

FIG. 3D is a cross-sectional view of a first transistor comprising GaN disposed above the carbonized layer, in accordance with certain aspects of the present disclosure.

FIG. 3E is a cross-sectional view of the first transistor having contacts formed thereon, in accordance with certain aspects of the present disclosure.

FIG. 3F is a cross-sectional view of various conductive elements and passive components embedded in one or more dielectric layers disposed above the first transistor, in accordance with certain aspects of the present disclosure.

FIG. 3G is a cross-sectional view of a second semiconductor die bonded to a first semiconductor die, in accordance with certain aspects of the present disclosure.

FIG. 3H is a cross-sectional view of conductive vias electrically coupling the first and second semiconductor dies, in accordance with certain aspects of the present disclosure.

FIG. 3I is a cross-sectional view of a semiconductor handle removed from the first semiconductor die, in accordance with certain aspects of the present disclosure.

FIG. 4 is a flow diagram of example operations for fabricating a semiconductor device, in accordance with certain aspects of the present disclosure.

FIG. 5 is a cross-sectional view of an example semiconductor device having heterogeneous transistors embedded in separate semiconductor dies, where one of the semiconductor dies has a gallium nitride (GaN) transistor disposed on a semiconductor layer with a Miller index of (111), in accordance with certain aspects of the present disclosure.

FIG. 6 is a cross-sectional view of an example semiconductor device having heterogeneous transistors embedded in separate semiconductor dies, where one of the semiconductor dies also has heterogeneous transistors disposed above a diamond substrate, in accordance with certain aspects of the present disclosure.

### DETAILED DESCRIPTION

Aspects of the present disclosure generally relate to a semiconductor device (such as a radio frequency front-end integrated circuit (RFFE IC)) having heterogeneous transistors integrated on diamond substrate with a carbonized layer. Co-integration of heterogeneous transistors (such as high voltage transistors and digital logic level transistors) on the diamond substrate provides performance and reliability benefits to the RFFE IC due to the enhanced thermal conductivity, higher resistivity, and lower loss-tangent of the diamond substrate, compared to other conventional substrates (e.g., silicon or sapphire). For example, the diamond substrate may improve heat dissipation and reduce crosstalk between digital and analog components (e.g., control logic and an RF power amplifier). Also, co-integration of the transistors and passive components (such as capacitors, inductors, and resistors) may reduce parasitic losses encountered when these components are interconnected as discrete components on the RFFE IC, especially when a discrete power amplifier is coupled to the RFFE IC. Further, co-integration of the heterogeneous transistors and passive components may provide cost benefits related to the fabrication process, such as enabling the fabrication of the heterogeneous transistors and passive components at a single fabrication facility.

### Example RE Front-End

An RF front-end typically includes electronic components such as control logic, switches, digital circuits, low noise amplifiers (LNAs), power amplifiers (PAs), etc. These electronic components may be assembled as discrete elements on a laminate substrate such as a glass-reinforced epoxy laminate (e.g., FR4) substrate. The discrete components on the RF front-end may lead to high parasitic resistances, inductances, and/or capacitances, resulting in significant parasitic losses, especially at 5G New Radio wireless access bands (such as sub-6 GHz (e.g., 450-6000 MHz) bands and/or mmWave bands (e.g., 24-30 GHz)).

The RF front-end may also suffer poor thermal dissipation and crosstalk between electronic components due to the substrate material, especially at the 5G New Radio wireless access bands. For example, gallium arsenide (GaAs) and silicon (Si) substrates may suffer from poor thermal conductivity resulting in significant self-heating on high-density components. Also, the gallium arsenide and silicon substrates may also provide worse substrate resistivity and loss tangent, which affects the crosstalk and interference encountered by the electronic components.

The discrete components may also affect the fabrication costs and cycle time of the RF front-end. The discrete components may be fabricated individually in separate fabrication facilities, on different size wafers, at significant cost and various cycle times. For example, gallium nitride (GaN), which provides suitable performance characteristics for power amplification, can be very expensive due to smaller diameter, more expensive GaN or silicon carbide (SiC) substrates and production in dedicated fabrication facilities (such as group III-V compound semiconductor facilities).

Certain aspects of the present disclosure generally relate to an example semiconductor device (such as an RF front-end integrated circuit) having heterogeneous transistors integrated on a diamond substrate with a carbonized layer. For example, the example semiconductor device may have gallium nitride (GaN) high electron mobility transistors (HEMT) configured for high voltage, high speed applications (e.g., a power amplifier (PA) on a transmit path of the RF front-end) and complementary metal-oxide-semiconductor (CMOS) transistors used in various applications (e.g., control logic, switches, digital circuits, and/or low noise amplifiers). The example semiconductor device may integrate the GaN transistors and passive components on a diamond substrate with a carbonized layer, which may facilitate improved GaN growth.

In aspects, a separately processed CMOS wafer may be bonded to the diamond substrate by a layer transfer bonding processing. The direct bonding between the GaN wafer and the CMOS wafer facilitates co-integration of the GaN transistors, CMOS transistors, and passive components while minimizing the parasitic losses (e.g., high parasitic resistances, inductances, and/or capacitances) caused by a wiring substrate or interposer disposed between the wafers.

The diamond substrate improves the performance, ruggedness, and reliability of the RF front-end due to vastly higher thermal conductivity, higher resistivity, and lower loss tangent of the diamond substrate compared to conventional substrates. The co-integration of the GaN transistors, CMOS transistors, and passive components (such as coupling capacitors, filters, etc.) on wafers via layer transfer may also provide cost and cycle time benefits as the transistor fabrication may be performed at a single semiconductor fabrication facility. The co-integration of the GaN transistors, CMOS transistors, and passive components may also significantly reduce parasitic losses due to component interconnects, which is highly beneficial for operating at high frequencies, such as 5G NR wireless access bands.

As used herein, high voltage applications may include operating electronic components (such as the example GaN HEMT described herein) at voltages significantly higher than digital power supply rails, for example, for maximizing power delivered by an RF PA to an antenna (output power may be proportional to the square of the voltage). A high speed device generally refers to a device that has sufficiently high transition frequency (f_{T}) and maximum frequency (fₘₐₓ) (e.g., typically 3 to 10 times the operating frequency) to ensure good performance (e.g., output power, gain, efficiency) at the operating frequency, such as at the 5G NR wireless access bands.

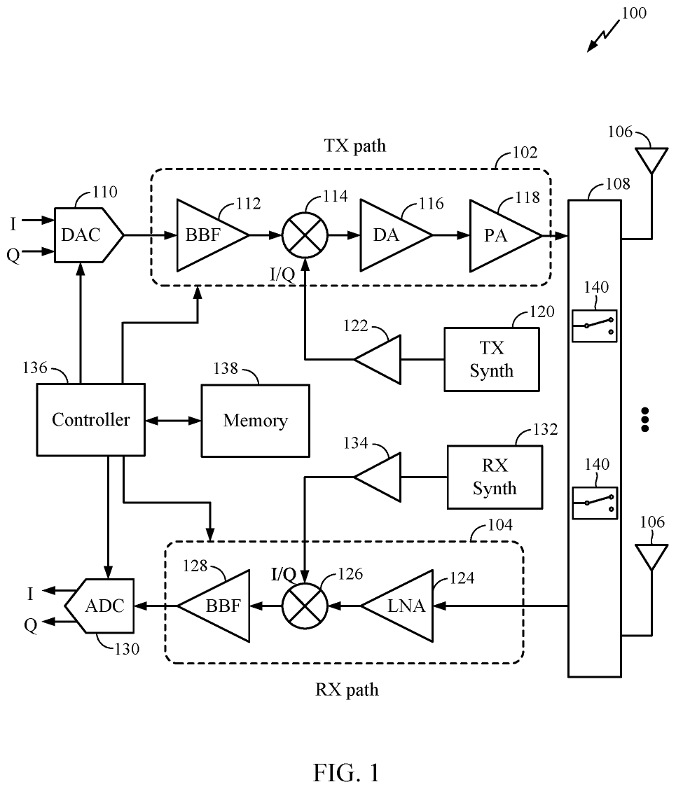

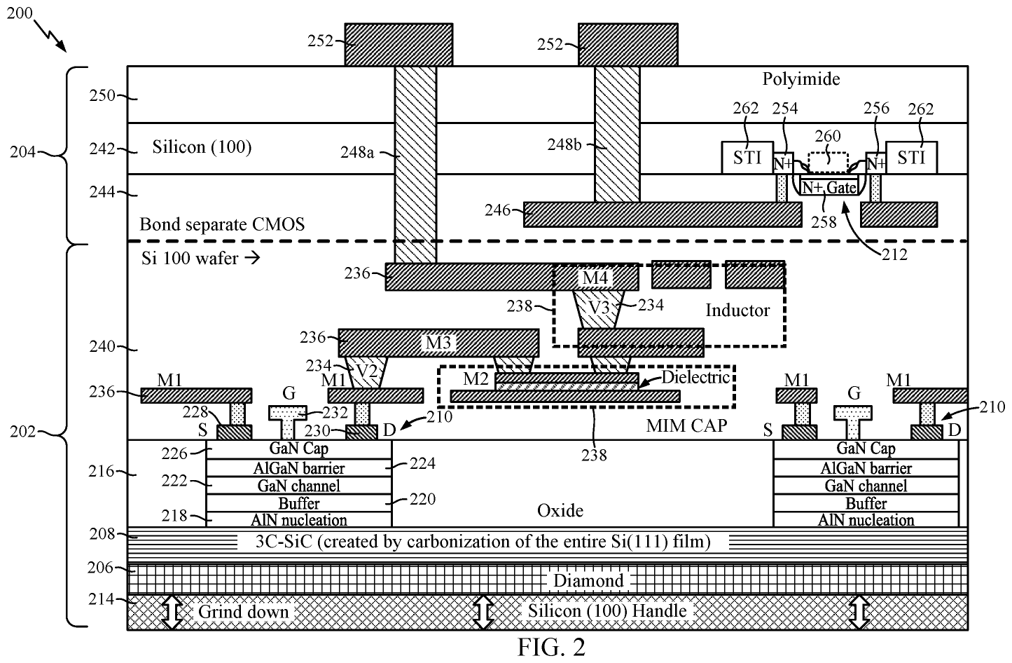

FIG. 1 is a block diagram of an example RF front-end 100, in accordance with certain aspects of the present disclosure. The RF front-end 100 may include heterogeneous transistors co-integrated on a diamond substrate with a carbonized layer as further described herein with respect to FIG. 2.

The RF front-end 100 includes at least one transmit (TX) path 102 (also known as a transmit chain) for transmitting signals via one or more antennas 106 and at least one receive (RX) path 104 (also known as a receive chain) for receiving signals via the antennas 106. When the TX path 102 and the RX path 104 share an antenna 106, the paths may be connected with the antenna via an interface 108, which may include any of various suitable RF devices, such as a switch 140, a duplexer, a diplexer, a multiplexer, and the like. The switch 140 may include a CMOS transistor as further described herein with respect to FIG. 2. In certain aspects, one or more switches 140 may be included in other components, such as a tunable capacitor array for a tunable filter or a frequency synthesizer, used in the RF front end 100.

Receiving in-phase (I) or quadrature (Q) baseband analog signals from a digital-to-analog converter (DAC) 110, the TX path 102 may include a baseband filter (BBF) 112, a mixer 114, a driver amplifier (DA) 116, and a power amplifier (PA) 118. The BBF 112, the mixer 114, the DA 116, and the PA 118 may be included in a semiconductor device such as a radio frequency integrated circuit (RFIC). As examples, the BBF 112 and/or mixer 114 may include CMOS transistors, whereas the PA 118 may include GaN HEMTs, as further described herein with respect to FIG. 2.

The BBF 112 filters the baseband signals received from the DAC 110, and the mixer 114 mixes the filtered baseband signals with a transmit local oscillator (LO) signal to convert the baseband signal of interest to a different frequency (e.g., upconvert from baseband to a radio frequency). This frequency conversion process produces the sum and difference frequencies between the LO frequency and the frequencies of the baseband signal of interest. The sum and difference frequencies are referred to as the beat frequencies. The beat frequencies are typically in the RF range, such that the signals output by the mixer 114 are typically RF signals, which may be amplified by the DA 116 and/or by the PA 118 before transmission by the antenna 106.

The RX path 104 may include a low noise amplifier (LNA) 124, a mixer 126, and a baseband filter (BBF) 128. The LNA 124, the mixer 126, and the BBF 128 may be included in a RFIC, which may or may not be the same RFIC that includes the TX path components. RF signals received via the antenna 106 may be amplified by the LNA 124, and the mixer 126 mixes the amplified RF signals with a receive local oscillator (LO) signal to convert the RF signal of interest to a different baseband frequency (e.g., downconvert). The baseband signals output by the mixer 126 may be filtered by the BBF 128 before being converted by an analog-to-digital converter (ADC) 130 to digital I or Q signals for digital signal processing. For example, the LNA 124 may be implemented with CMOS or GaN-based transistors, as further described herein with respect to FIG. 2.

While it is desirable for the output of an LO to remain stable in frequency, tuning to different frequencies indicates using a variable-frequency oscillator, which involves compromises between stability and tunability. Contemporary systems may employ frequency synthesizers with a voltage-controlled oscillator (VCO) to generate a stable, tunable LO with a particular tuning range. Thus, the transmit LO may be produced by a TX frequency synthesizer 120, which may be buffered or amplified by amplifier 122 before being mixed with the baseband signals in the mixer 114. Similarly, the receive LO may be produced by an RX frequency synthesizer 132, which may be buffered or amplified by amplifier 134 before being mixed with the RF signals in the mixer 126.

A controller 136 may direct the operation of the RF front-end 100, such as transmitting signals via the TX path 102 and/or receiving signals via the RX path 104. The controller 136 may be a processor, a digital signal processor (DSP), an application specific integrated circuit (ASIC), a field programmable gate array (FPGA) or other programmable logic device (PLD), discrete gate or transistor logic, discrete hardware components, or any combination thereof. The memory 138 may store data and program codes for operating the RF front-end 100. The controller 136 and/or memory 138 may include control logic (e.g., CMOS logic), which may include CMOS transistors as further described herein with respect to FIG. 2.

While FIG. 1 provides an RF front-end as an example application in which certain aspects of the present disclosure may be implemented to facilitate understanding, certain aspects described herein related to a semiconductor device having heterogeneous transistors integrated on a diamond substrate with a carbonized layer may be utilized in any of various other suitable electronic systems.

### Example Integration of Heterogeneous Transistors on a Diamond Substrate by Layer Transfer

FIG. 2 is a cross-sectional view of an example semiconductor device 200 that has heterogeneous transistors embedded in separate semiconductor dies, where one of the semiconductor dies has a GaN transistor disposed above a diamond substrate with a carbonized layer, in accordance with certain aspects of the present disclosure. As shown, the semiconductor device 200 may include a first semiconductor die 202 and a second semiconductor die 204. The first semiconductor die 202 includes a diamond substrate 206, a carbonized layer 208, and a first transistor 210; and the second semiconductor die 204 includes a second transistor 212.

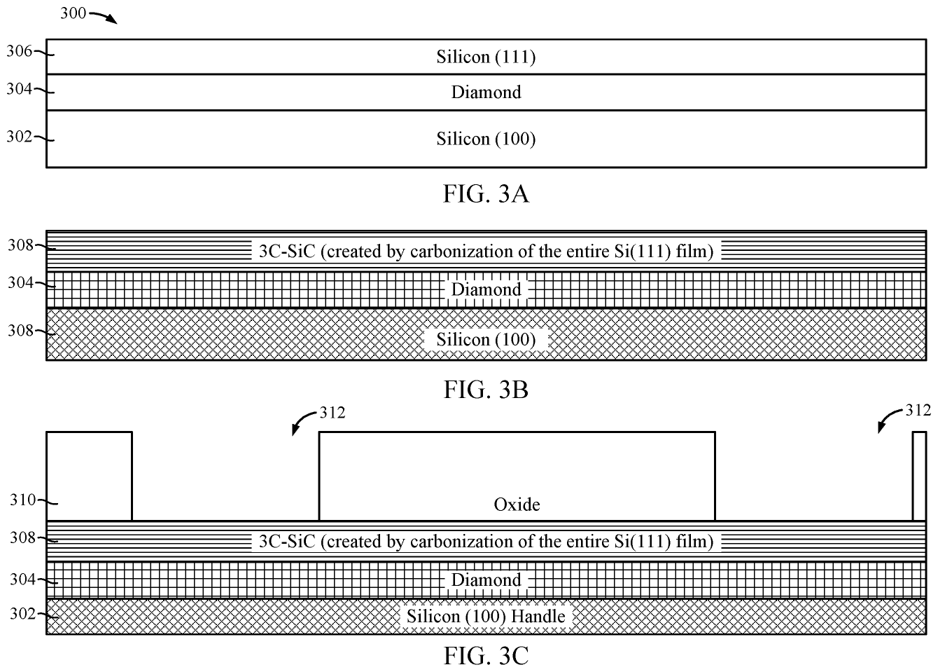

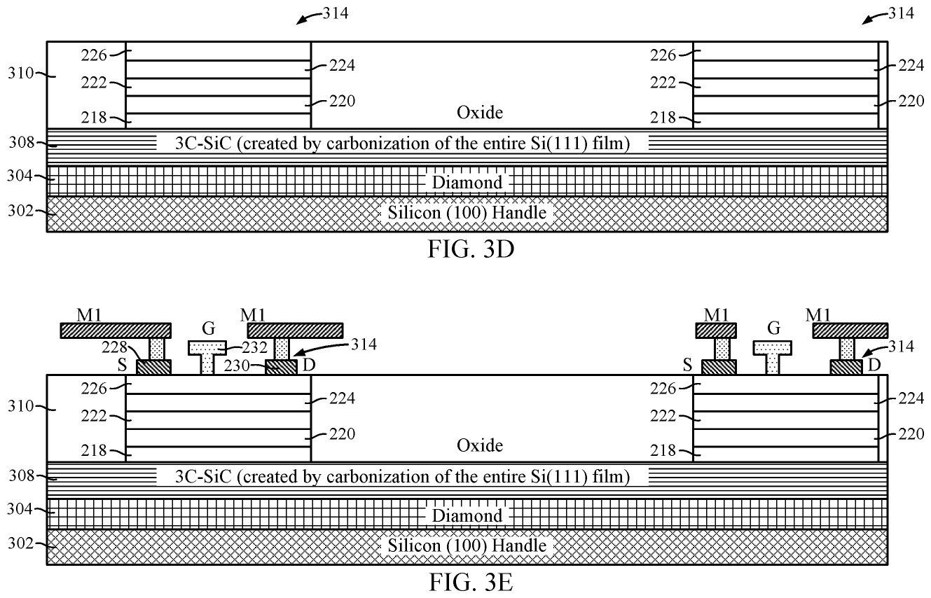

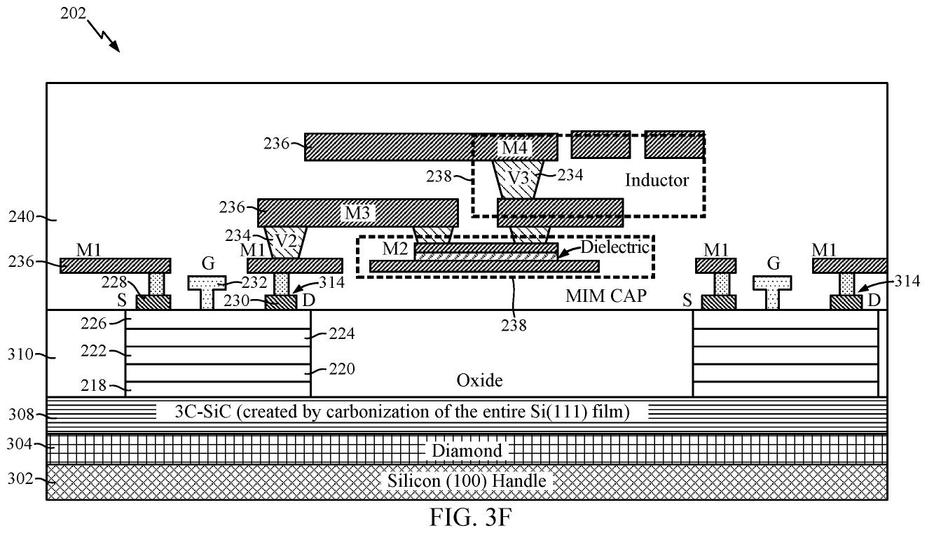

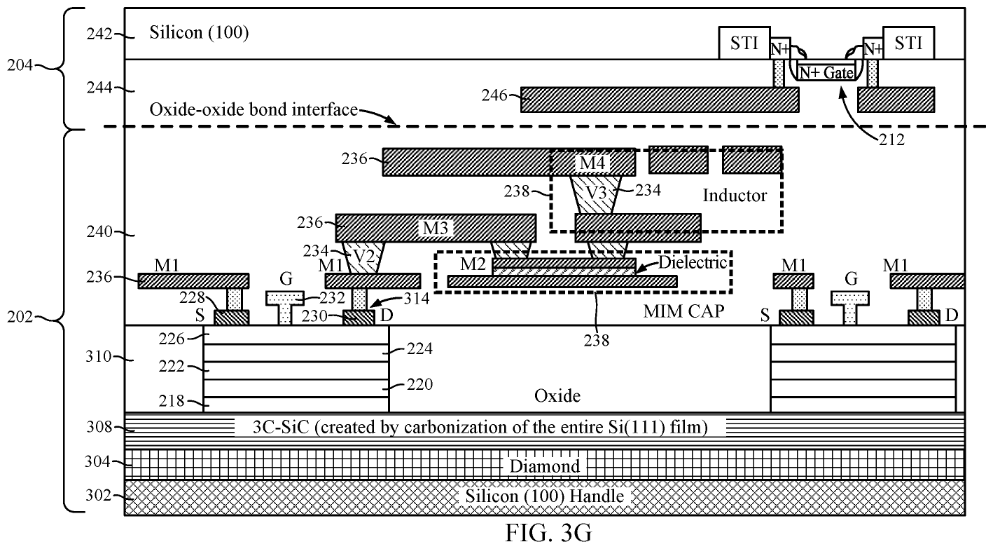

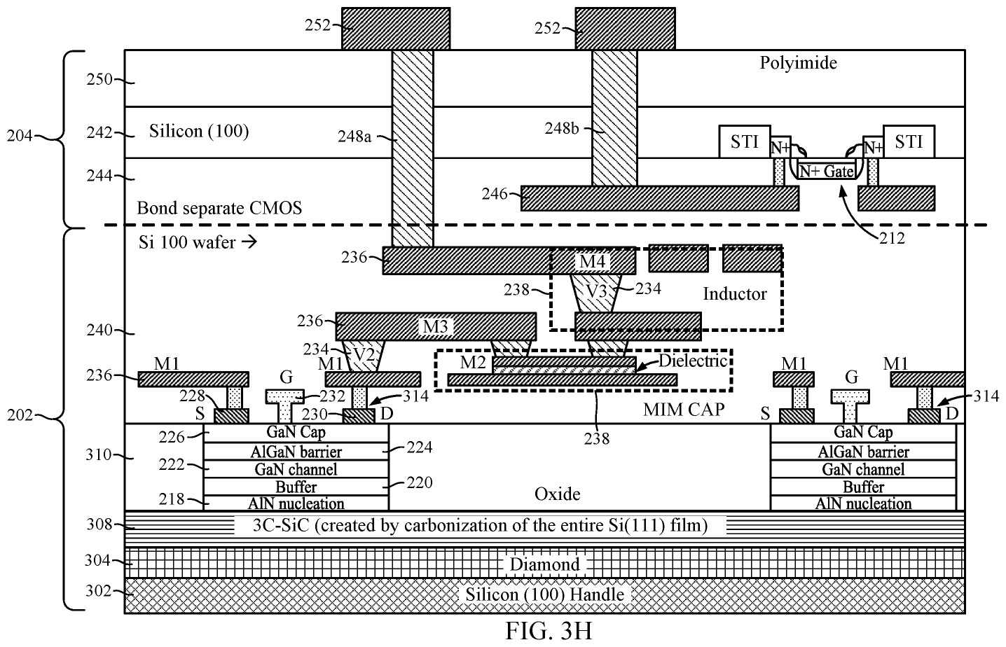

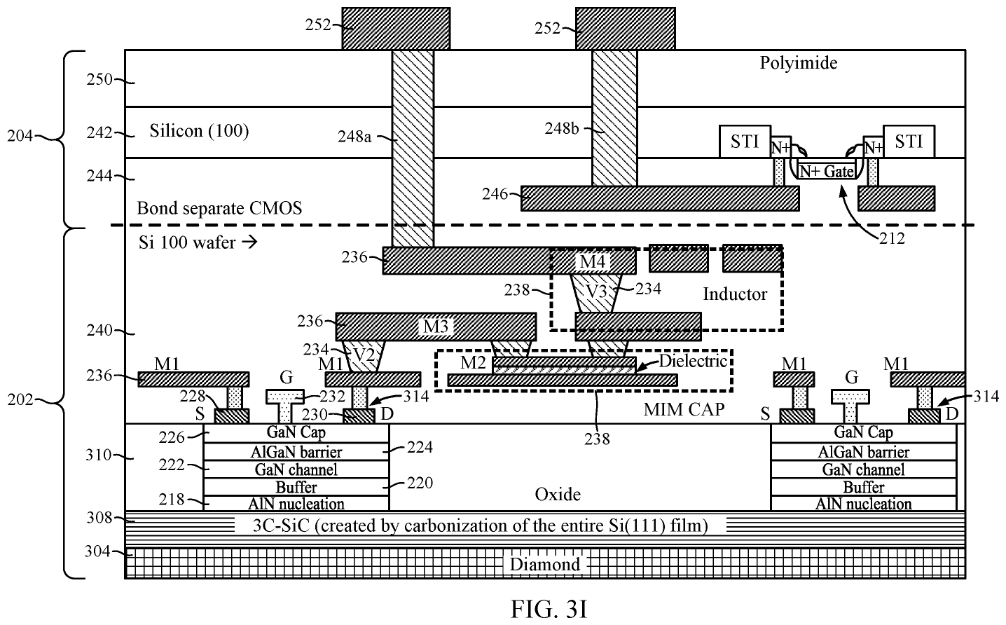

For certain aspects, the diamond substrate 206 may be a synthetic diamond produced by a chemical vapor deposition (CVD) process. The diamond substrate 206 may provide vastly higher thermal conductivity, higher resistivity, and lower loss-tangent compared to other substrate materials, such as silicon dioxide, silicon, or gallium arsenide. The diamond substrate 206 may be disposed between a semiconductor handle 214 (e.g., a bulk silicon support wafer or handle) and the carbonized layer 208. For example, the diamond substrate 206 may be a diamond layer included in a silicon-on-diamond wafer comprising a silicon layer, diamond substrate layer, and a bulk silicon handle as further described herein with respect to FIG. 3A. In certain aspects, the semiconductor handle 214 may be thinned or removed after fabricating the various components of the semiconductor device 200 with the semiconductor handle 214, for example, as further described herein with respect to FIG. 3I.

The carbonized layer 208 may include a carbide material such as a silicon carbide having a face-centered cubic (3C) polytype. In aspects, the carbonized layer 208 may have a Miller index of (111). The silicon carbide with a Miller index of (111) may facilitate improved epitaxy crystal growth of the first transistor 210 as further described herein with respect to FIG. 3D. In aspects, the carbonized layer 208 may have a thermal expansion coefficient suitably close to the first transistor 210, which may reduce strains on the GaN structure of the first transistor 210.

In certain aspects, the first semiconductor die 202 may further include a first dielectric region 216 having an oxide, such as silicon dioxide. As illustrated in FIG. 2, the dielectric region 216 may be a shallow trench isolation (STI) region configured to electrically isolate the first transistors 210, from each other and/or other electrical components. The dielectric region 216 may be disposed above the carbonized layer 208 and between the first transistors 210.

The first transistor 210 may comprise gallium nitride (GaN) and be a high electron mobility transistor (HEMT). The first transistor 210 may be configured for high speed, high voltage applications such as power amplification. For example, a power amplifier (e.g., PA 118 of FIG. 1) may include the first transistor 210 to amplify RF signals at high frequencies, such as in the 5G NR wireless access bands.

The first transistor 210 may include a nucleation layer 218, a buffer layer 220, a channel layer 222, a barrier layer 224, and a cap layer 226. The first transistor 210 may also include a source terminal 228, a drain terminal 230, and a gate terminal 232, each of which is disposed above the channel layer 222.

The nucleation layer 218 may be disposed above the carbonized layer 208. The nucleation layer 218 may be any suitable nucleation layer (e.g., an aluminum nitride (AlN) layer) that facilitates growth of a GaN structure, such as the first transistor 210, due to the lattice mismatch between the carbonized layer 208 and GaN transistor.

The buffer layer 220 may be disposed above the nucleation layer 218. As an example, the buffer layer 220 may include a graded aluminum gallium nitride (AlGaN) buffer. The buffer layer 220 may reduce strains on the GaN structure due to mismatches in thermal expansion coefficients and lattice constants between the GaN transistor and other materials, such as the diamond substrate 206, carbonized layer 208, dielectric region 216, and dielectric layers 240.

The channel layer 222 may be disposed above the buffer layer 220. The channel layer 222 may include gallium nitride, for example.

The barrier layer 224 may be disposed above the channel layer 222. The barrier layer 224 may include at least one of aluminum gallium nitride, indium aluminum nitride (e.g., In_{0.17}Al_{0.83}N), or any suitable lattice-matched barrier with GaN. An aluminum gallium nitride barrier may include from 20 to 30% aluminum, for example.

The cap layer 226 may be disposed above the barrier layer 224. The cap layer 226 may include gallium nitride, for instance. The barrier layer 224 and cap layer 226 may be configured to enhance the performance of the first transistor 210 for high speed, high voltage applications, such as by increasing the transition frequency and maximum frequency.

The first semiconductor die 202 may further comprise first conductive vias 234, first conductive layers 236, and various passive components 238. The first conductive vias 234, first conductive layers 236, and various passive components 238 may be embedded in first dielectric layers 240 disposed above the dielectric region 216. The first dielectric layers 420 may be layers of silicon dioxide, for example. The first conductive layers 236 may include metal layers (e.g., M1, M2, M3, M4, etc.) formed during a back-end of line (BEOL) process.

The passive components 238 may be electrically coupled (e.g., through the first conductive vias 234 and/or the first conductive layers 236) to at least one of the first transistor 210 or the second transistor 212. The passive components 238 may include a capacitor (e.g., a metal-insulator-metal (MIM) capacitor), inductor, or a resistor. In certain aspects, the first semiconductor die 202 may include a filter (e.g., the BBF 112 or BBF 128) having one or more of the passive components 238.

In aspects, the second semiconductor die 204 may include a semiconductor wafer 242, second dielectric layers 244, second conductive layers 246, second conductive vias 248a, 248b (collectively the second conductive vias 248), an insulation layer 250, and conductive pads 252.

The semiconductor wafer 242 may be a silicon wafer such as a fully processed silicon CMOS wafer. The second transistor 212 may be partially formed in the semiconductor wafer 242. In aspects, second dielectric regions 262 may be formed in the semiconductor wafer 242. For example, the second transistor 212 may be partially fabricated in a semiconductor region, which may then be selectively etched and filled with a dielectric to form the second dielectric regions 262.

The second dielectric layers 244 may be disposed below the semiconductor wafer 242. The second dielectric layers 244 may be layers of silicon dioxide. The second conductive layers 246 may be embedded in the second dielectric layers 244. The second conductive layers 246 may include metal layers (e.g., M1, M2, M3, M4, etc.) formed during a BEOL process.

The insulation layer 250 may include a polyimide insulation layer disposed above the semiconductor wafer 242. The conductive pads 252 may be electrically coupled to the first semiconductor die 202 and/or second semiconductor die 204. The conductive pads 252 may be disposed above the insulation layer 250 facilitate electrically coupling the semiconductor device 200 to other electrical devices such as a printed circuit board (PCB) or a mother board.

At least one of the second conductive vias 248 may intersect the second semiconductor die 204, such that the second conductive via 248 is electrically coupled to the first semiconductor die 202 as further described herein with respect to FIG. 3H. For instance, the second conductive via 248a intersects the insulation layer 250, semiconductor wafer 242, and dielectric layers 244, and the second conductive via 248a is electrically coupled to one of the first conductive layers 236. In aspects, the second conductive via 248a may be electrically coupled to one of the first transistors 210.

In aspects, at least one of the second conductive vias 248 may be electrically coupled to the second transistor 212 and/or other electrical components (not shown) embedded in the second semiconductor die 204. For instance, the second conductive via 248b is electrically coupled to one of the second conductive layers 246, which is electrically coupled to the second transistor 212.

The second transistor 212 may include a different semiconductor than the first transistor 210. For example, the second transistor 212 may include silicon instead of gallium nitride. Portions of the second transistor 212 may be formed in a semiconductor region such as the semiconductor handle 242. The semiconductor region may comprise any of various suitable semiconductor materials, such as silicon. The second transistor 212 may have a source region 254 and a drain region 256 implanted in the semiconductor region. The second transistor 212 may also include a gate region 258 and a channel region 260. The gate region 258 may be disposed below the channel region 260, which is formed in the semiconductor region. As an example, the gate region 258 may comprise a polysilicon gate, various work function metals, and/or conductive materials.

The second transistor 212 may be configured as an n-type metal-oxide-semiconductor (NMOS) transistor. For example, the source region 254 and the drain region 256 may be n+ doped semiconductors. While the examples provided herein are described with respect to an NMOS transistor to facilitate understanding, aspects of the present disclosure may also be applied to a p-type MOS (PMOS) transistor. For example, for a PMOS transistor, the source region 254 and drain region 256 may be p+ doped semiconductors. In aspects, the second semiconductor die 204 may include CMOS transistors. For example, the second transistor 212 may be a CMOS transistor.

The first and second transistors 210, 212 may be electrically coupled together and/or to various conductive elements including the first conductive vias 234 and the first conductive layers 236 in one or more dielectric layers 240. The conductive elements may electrically couple the first and second transistors 210, 212 to other electrical devices including, but not limited to, other transistors and/or the passive components 238 (e.g., a capacitor, inductor, and/or resistor). For example, the conductive elements may facilitate the co-integration of the first transistor 210, second transistor 212, and passive components 238 within the semiconductor device 200, thereby reducing parasitics encountered when, for example, some of the various components (such as a power amplifier, control logic, or filters) are discrete components.

According to certain aspects, the first and second semiconductor dies 202, 204 may be semiconductor dies without any packaging materials such as a casing material. The second semiconductor die 204 is disposed above the first semiconductor die 202. In aspects, the second semiconductor die 204 may be directly bonded to the first semiconductor die 202. For instance, surfaces of the dielectric layers 240, 244 of the first and second semiconductor dies 202, 204 may be coupled to each other using various layer transfer processes, such as direct wafer bonding of the silicon dioxide surfaces.

In certain aspects, the semiconductor device 200 may include a RF front-end integrated circuit (e.g., the RF front-end 100 or TX path 102). The RF front-end integrated circuit (RFFE IC) may include a power amplifier (e.g., PA 118) that includes the first transistor 210. The RFFE IC may include a switch (e.g., switch 140), control logic (e.g., the controller 136 and/or memory 138), or an LNA (e.g., LNA 124), any of which may include the second transistor 212.

FIGS. 3A-3I illustrate example operations for fabricating a semiconductor device that has heterogeneous transistors embedded in separate semiconductor dies, where one of the semiconductor dies has a GaN transistor disposed above a diamond substrate with a carbonized layer, in accordance with certain aspects of the present disclosure. The operations may be performed by a semiconductor fabrication facility, for example.

As shown in FIG. 3A, a silicon-on-diamond (SOD) wafer 300 may be formed. The SOD wafer 300 may include a silicon handle 302 (e.g., the first semiconductor handle 214), a diamond substrate 304 (e.g., the diamond substrate 206), and a silicon layer 306. The silicon layer 306 may be disposed above the diamond substrate 304, which may be disposed above the silicon handle 302. The silicon layer 306 may have a Miller index of (111).

Referring to FIG. 3B, the silicon layer 306 may be formed into a carbonized layer 308 (e.g., the carbonized layer 208) including a silicon carbide having a 3C polytype. A rapid thermal chemical vapor deposition (RTCVD) process may be used to deposit a carbon-based material (e.g., graphite and/or a hydrocarbon such as propane and hydrogen) on the silicon layer 306. In certain aspects, the RTCVD process may be performed at a temperature of about 1200° C.

As illustrated in FIG. 3C, a dielectric region 310 (e.g., the dielectric region 216) may be formed above the carbonized layer 308. As an example, the dielectric region 310 may include a layer of silicon dioxide, which may be deposited above the carbonized layer 308. After the dielectric region 310 is formed above the carbonized layer 308, cavities 312 may be formed in the dielectric region 310. As shown along the cross-sectional view of FIG. 3C, the cavities 312 may be separated by effective islands of the dielectric region 310. For example, a mask may be applied that isolates the GaN HEMT regions during an etching process (e.g., a dry or wet etching process), which removes a portion of the dielectric region 310 and forms the cavities 312. The cavities 312 may provide a mold for growing the GaN HEMT regions on the carbonized layer 308. In certain aspects, nitride spacers (not shown) may be formed on the sidewall of the cavities 312. The nitride spacer may serve as a barrier to prevent diffusion of the various layers of the GaN transistor into the dielectric region 310.

Referring to FIG. 3D, one or more first transistors 314 (e.g., the first transistor 210) may be formed above the carbonized layer 308 in the cavities 312. The first transistor 314 may include the nucleation layer 218, buffer layer 220, channel layer 222, barrier layer 224, and cap layer 226, as described herein with respect to FIG. 2. The layers of the first transistor 314 may be grown above the carbonized layer 308 and in the cavity 312 using a selective epitaxy growth process. For example, a mask may be applied to isolate the GaN HEMT region as the GaN transistor layers are epitaxial grown. The epitaxy growth process used to produce the first transistor 314 may include a molecular beam epitaxy (MBE) process or a metalorganic chemical vapor deposition (MOCVD) epitaxy process. The MBE process may be preferred due to the low temperatures encountered during the epitaxy process, and thus, reducing any diffusion or thermal strains during the epitaxy process. The carbonized layer 308 may improve the crystalline quality of the epitaxy growth process for the GaN lattice. For instance, the carbonized layer 308 may be well suited to the GaN lattice and the thermal expansion coefficients of the GaN transistor layers.

As depicted in FIG. 3E, the source terminal 228, drain terminal 230, and gate terminal 232 of the first transistor 314 may be formed above the channel layer 222. The gate terminal 232 may be formed as a T-gate (Schottky) by patterning silicon nitride (e.g., Si₃N₄) above the cap layer 226.

Referring to FIG. 3F, after forming the first transistors 314 (e.g., front-end of line (FEOL) process) on the carbonized layer 308, the BEOL process may be performed to form various conductive elements (e.g., the first conductive vias 234 and conductive layers 236) and passive components (e.g., the passive components 238). For instance, one or more dielectric layers 240 may be formed above the first transistors 314, and the conductive elements and passive components may be formed in the dielectric layers 240. The individual devices (e.g., the first transistors 314 and passive components 238 such as capacitors, resistors, inductors, etc.) may be electrically coupled with conductive elements, such as the first conductive vias 234 and first conductive layers 236, to form the various electrical devices (e.g., a BBF, mixer, PA, LNA, filter, control logic, etc.) of the first semiconductor die 202.

As shown in FIG. 3G, the second semiconductor die 204 may be coupled to the first semiconductor die 202. As an example, surfaces of the silicon oxide dielectric layers of the first and second semiconductor dies may be bonded together, for example, using an annealing process, surface activated bonding process, vacuum bonding process, etc. In certain cases, the second semiconductor die 204 may be bonded to the first semiconductor die 202 using various direct Sift/Sift bonding processes. In aspects, a wafer carrying multiple second semiconductor dies 204 may be bonded to another wafer carrying multiple first semiconductor dies 202, for example, using a layer transfer process. In certain cases, the second semiconductor die 204 may be formed on the semiconductor wafer 242 under a separate fabrication process than the fabrication process of the first semiconductor die 202. For instance, the second semiconductor die 204 may undergo a CMOS transistor fabrication process.

Referring to FIG. 3H, a planarization process (e.g., chemical-mechanical planarization) may be performed on the semiconductor wafer 242. The insulation layer 250 may be formed above the semiconductor wafer 242. For instance, the insulation layer 250 may be deposited on the semiconductor wafer 242. Cavities may be formed through the second semiconductor die 204 including the insulation layer 250, the semiconductor wafer 242, and the second dielectric layers 244. The second conductive vias 248 may be formed in the cavities (not shown), which may provide molds for the second conductive vias 248 that electrically couple the first semiconductor die 202 and/or second semiconductor die 204 to the conductive pads 252.

As depicted in FIG. 3I, the first semiconductor handle 302 may be removed. For instance, the first semiconductor handle 302 may be removed by grinding and/or etching the first semiconductor handle 302 to expose the diamond substrate 304.

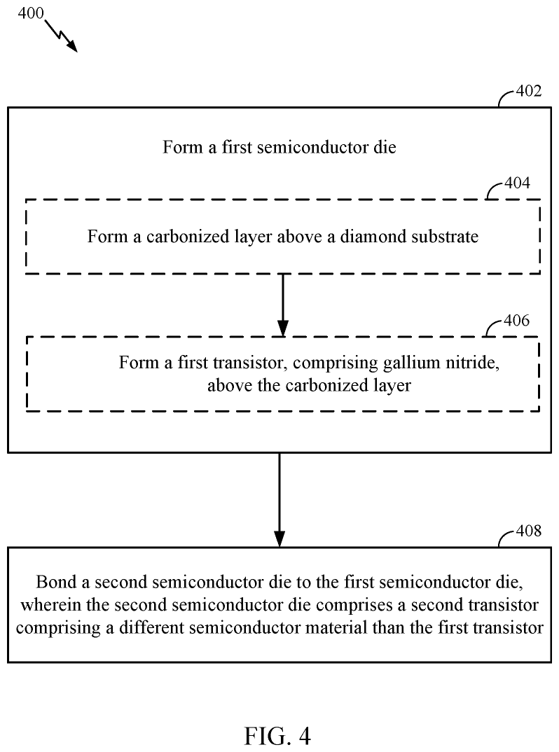

FIG. 4 is a flow diagram of example operations 400 for fabricating a semiconductor device (e.g., the semiconductor device 200 of FIG. 2), in accordance with certain aspects of the present disclosure. The operations 400 may be performed by a semiconductor fabrication facility, for example. In certain aspects, the semiconductor device may be a RF front-end integrated circuit (e.g., RF front-end 100 or the TX path 102).

The operations 400 begin, at block 402, by forming a first semiconductor die (e.g., the first semiconductor die 202). In aspects, forming the first semiconductor die at block 402 may include forming a carbonized layer (e.g., the carbonized layer 208) above a diamond substrate (e.g., the diamond substrate 206) at block 404, and forming a first transistor (e.g., the first transistor 210), comprising gallium nitride, above the carbonized layer at block 406. At block 408, a second semiconductor die (e.g., the second semiconductor die 204) may be bonded to the first semiconductor die, where the second semiconductor die comprises a second transistor (e.g., the second transistor 212) comprising a different semiconductor material than the first transistor.

In certain aspects, the second semiconductor die may be directly bonded to the first semiconductor die. For example, the second semiconductor die may be bonded to the first semiconductor die using an annealing process, surface activated bonding process, vacuum bonding process, etc. Bonding the second semiconductor die at block 408 may include electrically coupling the second semiconductor die to the first semiconductor die by use of through-silicon vias. For instance, after bonding the second semiconductor die to the first semiconductor die, cavities may be formed through the second semiconductor die, and the cavities may be filled with a conductive material to form conductive vias (e.g., the second conductive vias 248). In aspects, the conductive vias may be formed, for example, as described herein with respect to FIG. 3H.

In certain aspects, forming the carbonized layer at block 404 may include carbonizing at least a surface of a silicon layer (e.g., the silicon layer 306) disposed above the diamond substrate. As an example, an RTCVD process may be used to deposit a carbon-based material (e.g., graphite and/or a hydrocarbon such as propane and hydrogen) on the silicon layer to form a carbide, for example, as described herein with respect to FIG. 3B. In aspects, the surface of the silicon layer has a Miller index of (111). The carbonized layer may include a carbide such as a silicon carbide having a 3C polytype.

In certain aspects, forming the first transistor at block 406 may include growing layers of the first transistor using an epitaxial growth process, where the layers include a nucleation layer (e.g., the nucleation layer 218), a buffer layer (e.g., the buffer layer 220), a channel layer (e.g., the channel layer 222), a barrier layer (e.g., the barrier layer 224), and a cap layer (e.g., the cap layer 226). For instance, the first transistor may be grown in a cavity of a dielectric region (e.g., the dielectric region 310), for example, as described herein with respect to FIGS. 3C-3D.

According to certain aspects, passive components (e.g., the passive components 238) may be formed in one or more dielectric layers (e.g., the first dielectric layers 240) disposed above the dielectric region. The passive components and various conductive elements (e.g., the first conductive vias 234 and conductive layers 236) may be formed during a BEOL fabrication process.

In aspects, the semiconductor device may be fabricated in a RFFE IC. For instance, a power amplifier of the RFFE IC may include the first transistor. As an example, the RFFE IC may include a low noise amplifier, which includes the second transistor. In certain cases, the RFFE IC may include control logic, which includes the second transistor. In aspects, the control logic may include CMOS logic.

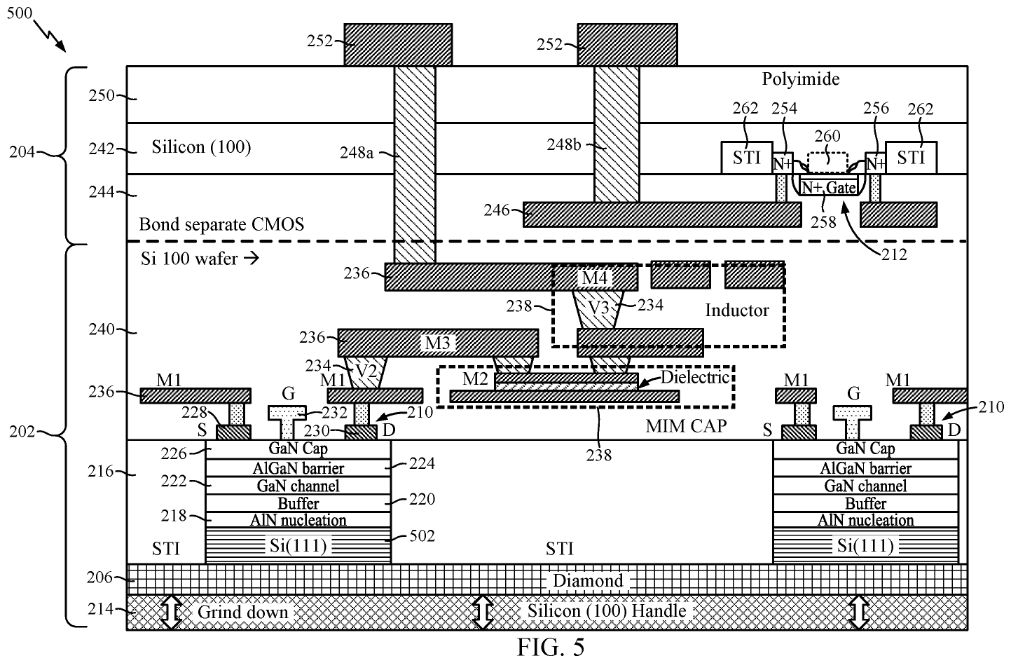

In aspects, instead of a carbonized layer, the GaN transistor may be grown on a semiconductor region (e.g., a silicon region) having a Miller index of (111). FIG. 5 illustrates a cross-sectional view of an example semiconductor device 500 that has the GaN transistor disposed above a diamond substrate with a semiconductor layer having a Miller index of (111), in accordance with certain aspects of the present disclosure. As shown, the semiconductor device 500 may include a semiconductor region 502 disposed between the first transistor 210 and the diamond substrate 206. As an example, the semiconductor device 500 may be similar to the semiconductor device 200, except the silicon layer of the SOD wafer is not carbonized. The semiconductor region 502 may be a silicon region having a Miller index of (111) to enable improved growth of the epitaxial layers of the GaN transistor. Referring to FIGS. 3A and 3C, rather than carbonizing the silicon layer 306 of the SOD wafer 300, the dielectric region 310 may be formed above the silicon layer 306, and the cavities 312 may be formed in the dielectric region 310. Growing the GaN transistor on the silicon layer of the SOD wafer may provide a more cost-effective alternative to growing the GaN transistor on the carbonized layer because a potentially lengthy and costly carbonization process can be skipped.

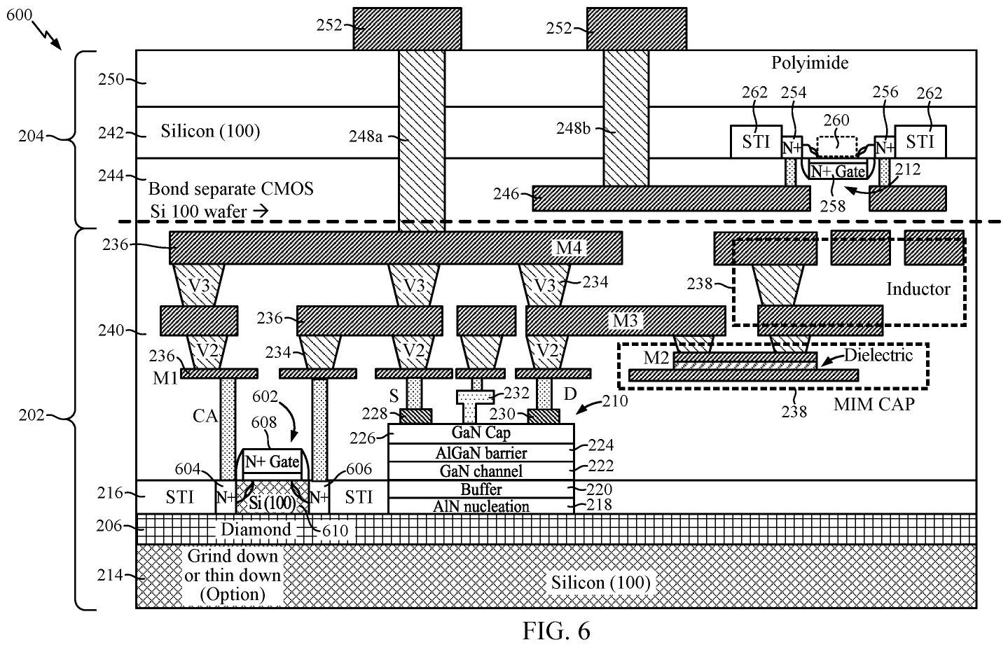

According to certain aspects, the GaN transistor may be grown on the diamond substrate of the SOD wafer, and in certain cases, a CMOS transistor may be formed on the silicon layer of the SOD wafer. FIG. 6 illustrates a cross-sectional view of an example semiconductor device 600 that has heterogeneous transistors disposed above the diamond substrate, in accordance with certain aspects of the present disclosure. As shown, the semiconductor device 600 includes a third transistor 602 disposed above the diamond substrate 206 of the first semiconductor die 202. As an example, the semiconductor device 600 may be similar to the semiconductor device 200, except the silicon layer of the SOD wafer is not carbonized and used to partially form a CMOS transistor.

The third transistor 602 may be disposed adjacent to the first transistor 210 on the diamond substrate 206. The third transistor 602 may be partially fabricated in the silicon layer of the SOD wafer. The silicon layer may then be selectively etched and filled with a dielectric to form the dielectric region 216. The third transistor 602 may include a different semiconductor than the first transistor 210. For example, the third transistor 602 may include silicon instead of gallium nitride. Portions of the third transistor 602 may be formed in a semiconductor region, such as the silicon layer 306 of the SOD wafer 300. The semiconductor region may comprise any of various suitable semiconductor materials, such as silicon. The third transistor 602 may have a source region 604 and a drain region 606 implanted in the semiconductor region. The third transistor 602 may also include a gate region 608 and a channel region 610. The gate region 608 may be disposed above the channel region 610 formed in the semiconductor region. For example, the gate region 608 may comprise a polysilicon gate, various work function metals, and/or conductive materials. In aspects, the CMOS transistor may be formed before the GaN transistor. By fabricating the CMOS transistor before the GaN transistor, the thermal budget impact to the CMOS is mitigated.

The following description provides examples, and is not limiting of the scope, applicability, or examples set forth in the claims. Changes may be made in the function and arrangement of elements discussed without departing from the scope of the disclosure. Various examples may omit, substitute, or add various procedures or components as appropriate. For instance, the methods described may be performed in an order different from that described, and various steps may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method which is practiced using other structure, functionality, or structure and functionality in addition to, or other than, the various aspects of the disclosure set forth herein. It should be understood that any aspect of the disclosure disclosed herein may be embodied by one or more elements of a claim. The word “exemplary” is used herein to mean “serving as an example, instance, or illustration.” Any aspect described herein as “exemplary” is not necessarily to be construed as preferred or advantageous over other aspects.

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes, and variations may be made in the arrangement, operation, and details of the methods and apparatus described above without departing from the scope of the claims.

1. A semiconductor device comprising:
a first semiconductor die comprising:
a diamond substrate,
a carbonized layer disposed above the diamond substrate, and
a first transistor disposed above the carbonized layer, the first transistor comprising gallium nitride; and
a second semiconductor die disposed above the first semiconductor die, wherein the second semiconductor die comprises a second transistor comprising a different semiconductor material than the first transistor.

2. The semiconductor device of claim 1, wherein the carbonized layer comprises silicon carbide having a face-centered cubic (3C) polytype.

3. The semiconductor device of claim 1, wherein the carbonized layer has a Miller index of (111).

4. The semiconductor device of claim 1, wherein the first transistor comprises a high electron mobility transistor.

5. The semiconductor device of claim 1, wherein the first transistor further comprises:
a nucleation layer disposed above the carbonized layer;
a buffer layer disposed above the nucleation layer; and
a channel layer disposed above the buffer layer.

6. The semiconductor device of claim 4, wherein the first transistor further comprises:
a barrier layer disposed above the channel layer; and
a cap layer disposed above the barrier layer.

7. The semiconductor device of claim 1, wherein the first semiconductor die comprises one or more passive components disposed above the diamond substrate and electrically coupled to at least one of the first transistor or the second transistor.

8. The semiconductor device of claim 1, wherein the first semiconductor die is bonded to the second semiconductor die.

9. A radio frequency front-end (RFFE) integrated circuit (IC) comprising the semiconductor device of claim 1, wherein a power amplifier of the RFFE IC includes the first transistor.

10. The RFFE IC of claim 9, further comprising a low noise amplifier, wherein the low noise amplifier comprises the second transistor in the second semiconductor die.

11. The RFFE IC of claim 9, further comprising control logic, wherein the control logic comprises the second transistor in the second semiconductor die.

12. The RFFE IC of claim 11, wherein the control logic comprises complementary metal-oxide-semiconductor (CMOS) logic.

13. A method of fabricating a semiconductor device, comprising:
forming a first semiconductor die, wherein forming the first semiconductor die comprises:
forming a carbonized layer above a diamond substrate, and
forming a first transistor, comprising gallium nitride, above the carbonized layer; and
bonding a second semiconductor die to the first semiconductor die, wherein the second semiconductor die comprises a second transistor comprising a different semiconductor material than the first transistor.

14. The method of claim 13, wherein the bonding comprises electrically coupling the second semiconductor die to the first semiconductor die by use of through-silicon vias.

15. The method of claim 13, wherein forming the first transistor comprises growing layers of the first transistor using an epitaxial growth process, the layers including a nucleation layer, a buffer layer, a channel layer, a barrier layer, and a cap layer.

16. The method of claim 13, wherein forming the carbonized layer comprises carbonizing at least a surface of a silicon layer disposed above the diamond substrate, wherein the at least the surface of the silicon layer has a Miller index of (111).

17. The method of claim 16, wherein the carbonized layer comprises silicon carbide having a face-centered cubic (3C) polytype.
